(19) United States
(12) Patent Application Publication
(10) Pub. No.: US 2017/0130913 A1
(43) Pub. Date: May 11, 2017

(54) LASER POINTER

(71) Applicant: FOXCONN INTERCONNECT TECHNOLOGY LIMITED, Grand Cayman (KY)

(72) Inventors: CHI-MING CHEN, New Taipei (TW); DE-GANG ZHANG, Kunshan (CN); HAO JIANG, Kunshan (CN)

(21) Appl. No.: 15/348,852

(22) Filed: Nov. 10, 2016

(30) Foreign Application Priority Data
Nov. 10, 2015 (CN) 201510758506.3

(51) Int. Cl. F21L 4/00; H05K 5/00; H01R 24/60; H02J 7/00; H03K 17/96; H05K 5/02; H05K 5/03

(52) U.S. Cl. CPC F21L 4/00; H05K 5/0247; H05K 5/0039; H05K 5/03; H02J 7/0045; H02J 7/0052; H03K 17/96; H01R 24/60; H05K 1/181

(57) ABSTRACT

A laser pointer 100 includes a case (1), a laser module (2), a printed circuit board assembly (3) and a charging connector (6). The case (1) includes a lighting end (12) at a front end thereof, a mounting port (13) at a rear end thereof, a receiving cavity between the lighting end and the mounting port, and an inner wall (15). The laser module (2) and the printed circuit board assembly (3) are received in the receiving cavity (14). The printed circuit board assembly connects with the rear side of the laser module (2). The charging connector (6) mounted on the rear end of the printed circuit board assembly (3) electrically connects to the laser module (2) through the printed circuit board assembly (3).

### BACKGROUND OF THE INVENTION

1. Field of the Invention

The present disclosure relates generally to a laser pointer, and more particularly to a laser pointer without batteries.

2. Description of Related Arts

China Patent No. CN203659256U, issued on Jun. 18, 2014, discloses a laser pointer powered by lithium batteries. The laser pointer includes a case, lithium batteries, a PCB control board, a transmitting module, and a laser control module. The laser control module electrically connects to a laser head. The transmitting module and the laser control module are disposed on the PCB control board. The laser control module is powered by lithium batteries. The battery in the laser pointer increases its volume and weight.

An improved laser pointer is desired.

### SUMMARY OF THE INVENTION

Accordingly, an object of the present invention is to provide an laser pointer with small size and light weight.

To achieve the above object, a laser pointer includes a case, a laser module, a printed circuit board assembly and a charging connector. The case includes a lighting end at a front end thereof, a mounting port at a rear end thereof, a receiving cavity between the lighting end and the mounting port, and an inner wall. The laser module and the printed circuit board assembly are received in the receiving cavity. The printed circuit board assembly connects with the rear side of the laser module. The charging connector mounted on the rear end of the printed circuit board assembly electrically connects to the laser module through the printed circuit board assembly and is adapted to supply an external power to the laser module.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a laser pointer and charging wire in accordance with present invention;

FIG. 2 is an exploded view of the laser pointer as shown in FIG. 1;

FIG. 3 is a further perspective exploded view of the laser pointer as shown in FIG. 2;

FIG. 4 is another exploded view of the laser pointer as show in FIG. 3; and

FIG. 5 is across section view of the laser pointer taken along line 5-5 in FIG. 1.

### DETAILED DESCRIPTION OF THE PREFERRED EMBODIMENT

Reference will now be made in detail to the preferred embodiment of the present invention.

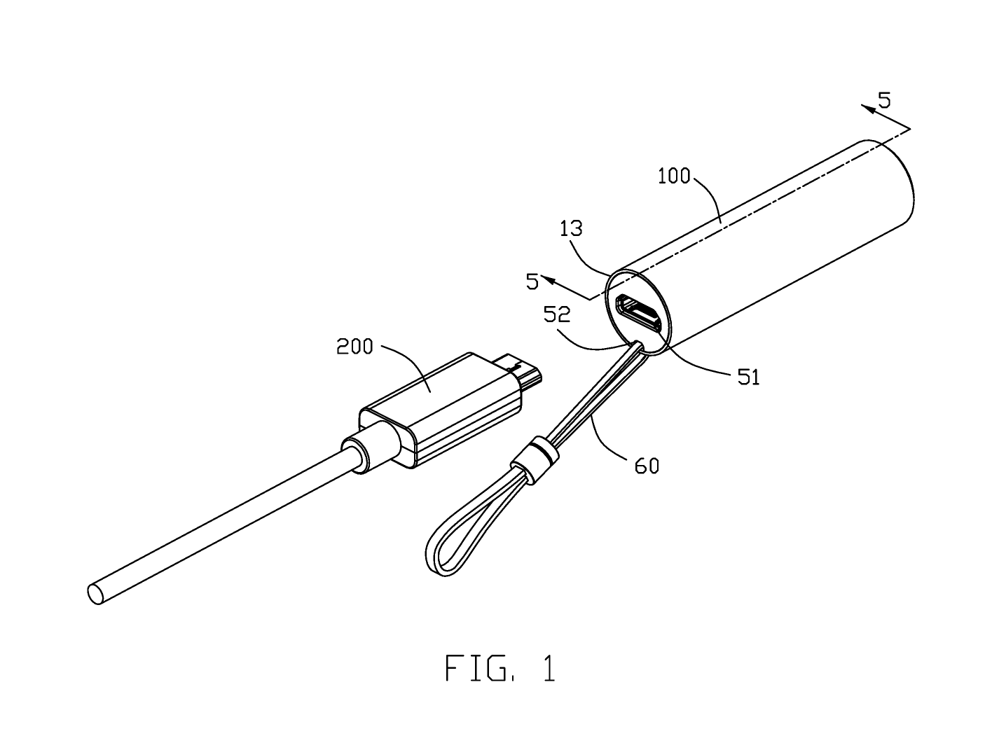

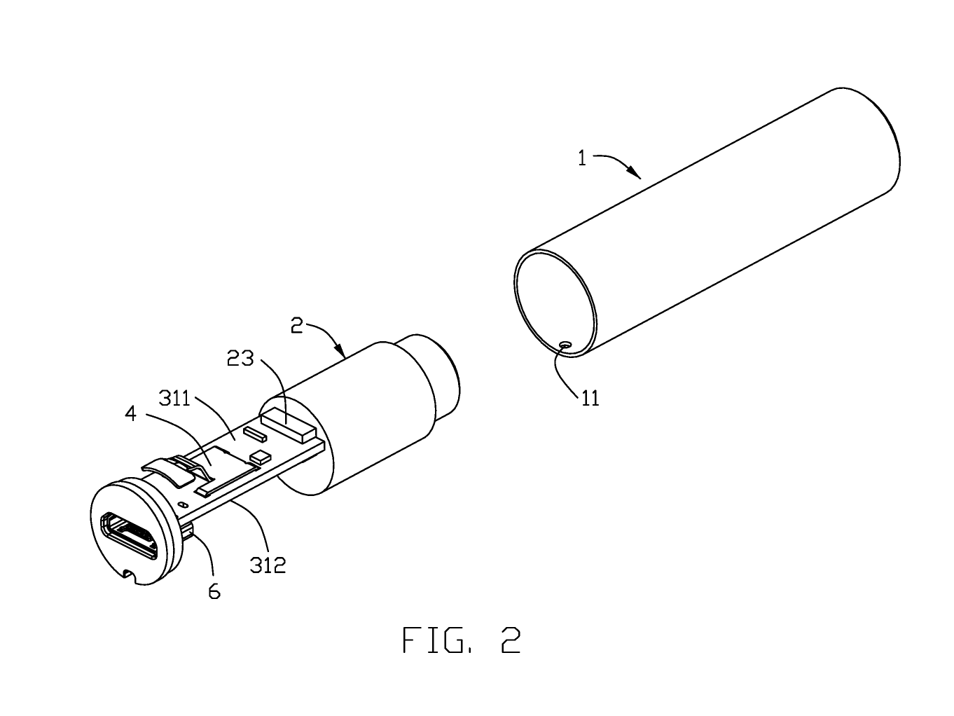

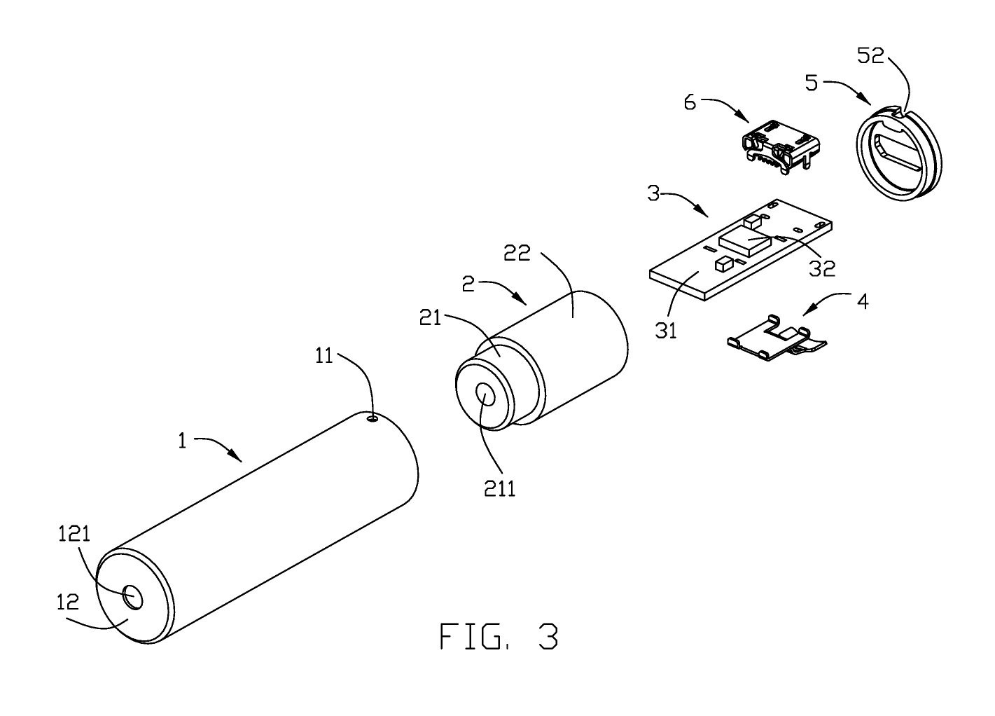

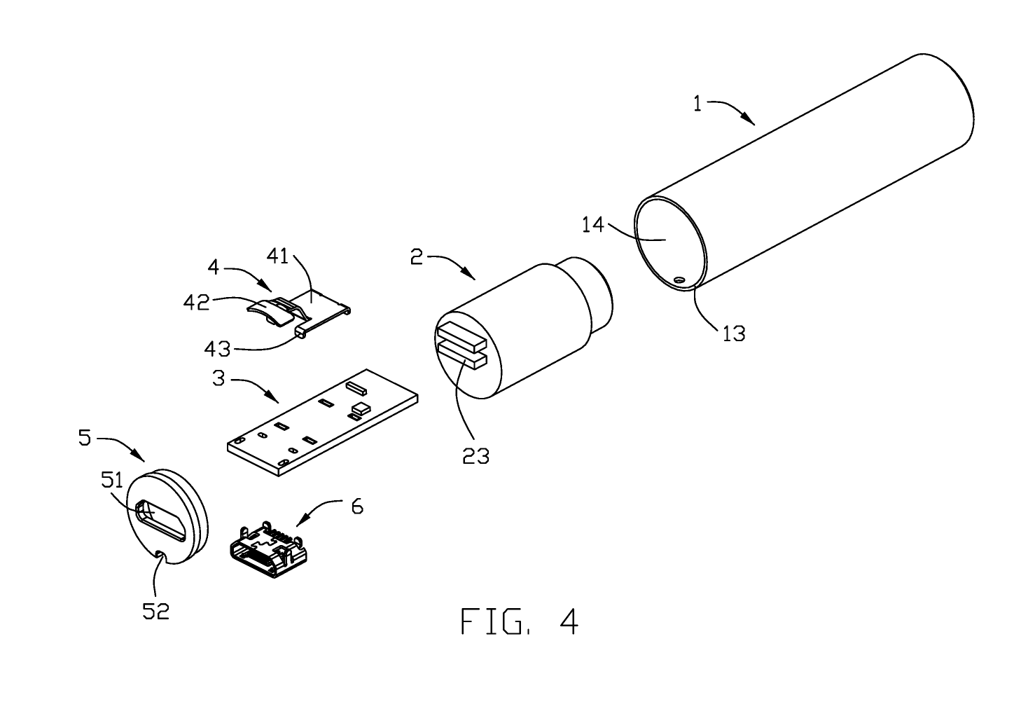

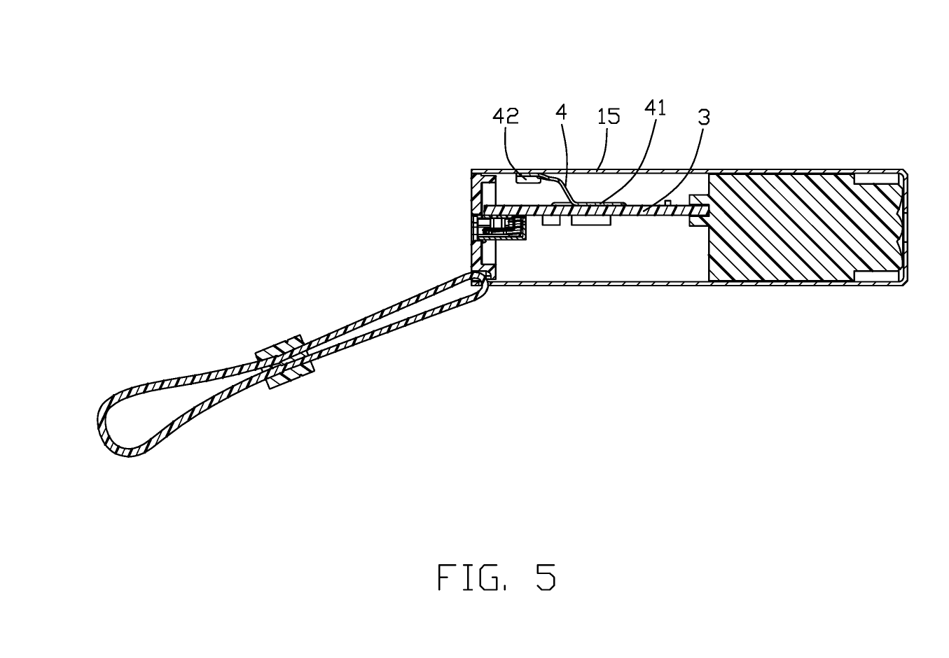

Referring to FIGS. 1 to 5, a laser pointer comprises a case 1, a laser module 2 received in the case 1, a printed circuit board assembly 3 connecting with the rear side of the laser module 2, a touch sensing plate 4 mounted on the printed circuit board assembly 3, a rear cover 5, and a charging connector 6. Notably, a cable unit 200 is adapted to be mated with the charging connector 6 for power supply wherein such a cable unit 200 may be externally connected to a notebook computer or even a movable power source/bank.

The case 1 includes a lighting end 12 at a front end thereof, a mounting port 13 at a rear end thereof, a receiving cavity 14 between the lighting end 12 and the mounting port 13, an inner wall 15, and a pendant hole 11 at the rear end. The lighting end 12 defines a light hole 121 in the middle thereof. The laser module 2 defines a light emitter 211 opposite to the light hole 121.

The laser module 2 includes a first case 21 and a second case 22, the diameter of the second case 22 being larger than the diameter of the first case 21. The laser module 2 defines a light emitter 211 opposite to the light hole 121. The rear of the laser module 2 has two horizontal plates 23. The front end of the printed circuit board assembly 3 is held between two horizontal plates 23 and electrically connects to the laser module 2.

The printed circuit board assembly 3 includes a printed circuit board 31 and electronic elements 32 mounted on the top side 311 and bottom side 312 of the printed circuit board 31. The printed circuit board 31 includes two opposite ends 311 and 312. The touch sensing plate 4 is installed on the top side 311 and the charging connector 6 is arranged on the bottom side 312.

The touch sensing plate 4 is mounted between the inner wall 15 and the printed circuit board assembly 3. The touch sensing plate 4 includes a main board 41, a contact plate 42 upwardly extending from the main board 41, and a plurality of connection pins 43 downwardly extending from the main board 41. The contact plate 42 is curved and contacts the inner wall 15. The connection pins 43 are fixedly connected with the printed circuit board 31. The laser pointer 100 further includes a touch sensing plate 4. After the laser pointer 100 is charged by the charging connector 6, the touch sensing plate 4 electrically connects to the inner wall 15 and excites laser when a user touches the case 1. The laser will delay 5 seconds to turn off after not touching the case 1.

The rear cover 5 is received in the mounting port 13. The middle of the rear cover 5 has an insert port 51 receiving the rear end of the charging connector 6. The rear cover 5 has a groove 52 corresponding to the pendant hole 11 of the case 1. By using an accessory pendant line through the pendant hole 11 and groove 52, it is easy to hang the pointer in keychains, backpacks, zipper buckles, etc.

The charging connector 6 connected to the rear end of the printed circuit board assembly 3 electrically connects to the laser module 2 by the printed circuit board assembly 3. The charging connector 6 is used for connecting external power source to supply power to the laser module 2. The charging connector 6 can be a USB connector or other electrical connectors. Preferably, the charging connector is a Micro USB electrical connector.

While a preferred embodiment in accordance with the present invention has been shown and described, equivalent modifications and changes known to persons skilled in the art according to the spirit of the present invention are considered within the scope of the present invention as described in the appended claims.

What is claimed is:

1. A laser pointer comprising:
a case including a lighting end at a front end thereof, a mounting port at a rear end thereof, a receiving cavity between the lighting end and the mounting port, and an inner wall;
a laser module received in the receiving cavity;
a printed circuit board assembly received in the receiving cavity and connecting to the rear side of the laser module; and
a charging connector mounted on the rear end of the printed circuit board assembly; wherein
the charging connector electrically connects to the laser module through the printed circuit board assembly and is adapted to supply an external power to the laser module.

2. The laser pointer as claimed in claim 1, wherein the laser pointer includes a touch sensing plate located between the inner wall and the printed circuit board assembly.

3. The laser pointer as claimed in claim 2, wherein the touch sensing plate includes a main board, a contact plate upwardly extending from the main board, and a plurality of connection pins downwardly extending from the main board, the contact plate being curved and fitting the inner wall, the plurality of connection pin being fixedly connected with the printed circuit board assembly.

4. The laser pointer as claimed in claim 2, wherein the printed circuit board assembly includes a printed circuit board and electronic elements mounted on the printed circuit board, the printed circuit board includes two opposite ends, the touch sensing plate is installed on one of the two opposite ends, and the charging connector is arranged on the other end.

5. The laser pointer as claimed in claim 1, wherein the lighting end defines a light hole in the middle thereof, and the laser module defines a light emitter opposite to the light hole.

6. The laser pointer as claimed in claim 1, wherein the rear end of the laser module has two horizontal plates, and the front end of the printed circuit board assembly is clamped between the two horizontal plates and electrically connects to the laser module.

7. The laser pointer as claimed in claim 1, wherein the laser pointer includes a rear cover received in the mounting port, and a middle of the rear cover has an insert port receiving the rear end of the charging connector.

8. The laser pointer as claimed in claim 1, wherein the charging connector is a USB electrical connector.

9. The laser pointer as claimed in claim 1, wherein the charging connector is a Micro USB electric connector.

10. The laser pointer as claimed in claim 1, wherein the rear end of the case has a pendant hole.

11. A laser pointer assembly comprising:
a case forming a lighting emitting hole and a charging connector hole spaced from each other with a receiving cavity therebetween;
a laser module received in the receiving cavity and adjacent to the lighting emitting hole;
a printed circuit board assembly received in the receiving cavity and adjacent to the charging connector hole and electrically connected to the laser module,
a charging connector mounted on an edge area of the printed circuit board assembly and adjacent to the charging connector hole; wherein
the charging connector electrically connects to the laser module through the printed circuit board assembly and is adapted to supply an external power to the laser module.

12. The laser pointer assembly as claimed in claim 11, wherein said lighting emitting hole and said charging connector hole are opposite to each other in an axial direction of the case having a cylindrical form.

13. The laser pointer assembly as claimed in claim 11, further including a sensing plate mounted upon the printed circuit board assembly and touching an inner wall of the case so as to activate corresponding laser once a user touches the case.

14. The laser pointer assembly as claimed in claim 11, wherein said laser module and said printed circuit board assembly are essentially arranged adjacent to each other along an axial direction of said case forming a cylindrical form.

15. The laser pointer assembly as claimed in claim 11, wherein said case forms a cylindrical structure with a circular cross-sectional configuration, said charging connector is located at a middle level along a corresponding diametrical direction while said printed circuit board assembly is offset from said middle level.

16. The laser pointer assembly as claimed in claim 11, further including a cable unit connected to the charging connector via said charging connector hole.
